(19) United States
(12) Patent Application Publication
(10) Pub. No.: US 2025/0120251 A1
(43) Pub. Date: Apr. 10, 2025

(54) LIGHT EMITTING DIODE, DISPLAY SUBSTRATE AND DISPLAY DEVICE

(71) Applicant: BOE TECHNOLOGY GROUP CO., LTD., Beijing (CN)

(72) Inventors: Changyen WU, Beijing (CN); Juanjuan YOU, Beijing (CN); Wei QUAN, Beijing (CN); Cheng XU, Beijing (CN); Dandan ZHOU, Beijing (CN)

(73) Assignee: BOE TECHNOLOGY GROUP CO., LTD., Beijing (CN)

(21) Appl. No.: 18/565,779

(22) PCT Filed: Nov. 30, 2022
(86) PCT No.: PCT/CN2022/135391

§ 371 Date: Nov. 30, 2023

(51) Int. Cl. H10K 50/19; H10K 59/131; H10K 59/32; H10K 101/40

(52) U.S. Cl. CPC H10K 50/19; H10K 59/131; H10K 59/32; H10K 2101/40

(57) ABSTRACT

A light emitting diode, a display substrate and a display device. In the light emitting diode, the first light emitting structure includes a first hole transport layer, a first light emitting layer and a first electron transport layer; the second light emitting structure includes a second hole transport layer and a second light emitting layer, an absolute value of a first energy level difference between a LUMO energy level of the first light emitting layer and a LUMO energy level of the first electron transport layer is less than an absolute value of a second energy level difference between a HOMO energy level of the second light emitting layer and a HOMO energy level of the second hole transport layer.

### TECHNICAL FIELD

Embodiments of the present disclosure relate to a light emitting diode, a display substrate and a display device.

### BACKGROUND

With the continuous development of display technology, organic light emitting diode display devices (OLEDs) have become a research hotspot and a technological development direction for the current manufacturers due to their advantages such as fast response speed, wide color gamut, high contrast, lightweight design, self-illumination, and wide viewing angle. On the other hand, organic light emitting display devices do not require backlight units and can be formed on flexible substrates made of flexible materials, which can also be applied to flexible display technology.

At present, organic light emitting diode display devices (OLEDs) have been widely used in various electronic products, ranging from small electronic products such as smart bracelets, smartwatches, smartphones, tablet computers and so on to large electronic products such as laptop computers, desktop computers, televisions and so on. Therefore, the market demand for active matrix organic light-emitting diode display devices is also increasing.

### SUMMARY

In this regard, embodiments of the present disclosure provide a light emitting diode, a display substrate and a display device. The light emitting diode includes: a first electrode, a first light emitting structure, a first charge generation layer, a second light emitting structure and a second electrode; the first light emitting structure is located on a side of the first electrode, the first charge generation layer is located on a side of the first light emitting structure away from the first electrode, the second light emitting structure is located on a side of the first charge generation layer away from the first light emitting structure; and the second electrode is located on a side of the second light emitting structure away from the first charge generation layer. The first light emitting structure includes a first hole transport layer, a first light emitting layer and a first electron transport layer, the first hole transport layer is located between the first electrode and the first light emitting layer, the first electron transport layer is located between the first charge generation layer and the first light emitting layer; the second light emitting structure comprises a second hole transport layer and a second light emitting layer, and the second hole transport layer is located between the first charge generation layer and the second light emitting layer, an absolute value of a first energy level difference between a LUMO energy level of the first light emitting layer and a LUMO energy level of the first electron transport layer is less than an absolute value of a second energy level difference between a HOMO energy level of the second light emitting layer and a HOMO energy level of the second hole transport layer. Therefore, the light emitting diode can improve the light emitting efficiency.

At least one embodiment of the present disclosure provides a light emitting diode, which includes: a first electrode; a first light emitting structure, located on a side of the first electrode; a first charge generation layer, located on a side of the first light emitting structure away from the first electrode; a second light emitting structure, located on a side of the first charge generation layer away from the first light emitting structure; and a second electrode, located on a side of the second light emitting structure away from the first charge generation layer; the first light emitting structure comprises a first hole transport layer, a first light emitting layer and a first electron transport layer, the first hole transport layer is located between the first electrode and the first light emitting layer, and the first electron transport layer is located between the first charge generation layer and the first light emitting layer; the second light emitting structure comprises a second hole transport layer and a second light emitting layer, the second hole transport layer is located between the first charge generation layer and the second light emitting layer, an absolute value of a first energy level difference between a LUMO energy level of the first light emitting layer and a LUMO energy level of the first electron transport layer is less than an absolute value of a second energy level difference between a HOMO energy level of the second light emitting layer and a HOMO energy level of the second hole transport layer.

For example, in the light emitting diode provided by an embodiment of the present disclosure, the light emitting diode further includes: a second charge generation layer, located on a side of the second light emitting structure away from the first charge generation layer; and a third light emitting structure, located between the second charge generation layer and the second electrode; the second light emitting structure further comprises a second electron transport layer, and the second electron transport layer is located between the second light emitting layer and the second charge generation layer.

For example, in the light emitting diode provided by an embodiment of the present disclosure, the third light emitting structure comprises a third hole transport layer, a third light emitting layer and a third electron transport layer, the third hole transport layer is located between the second charge generation layer and the third light emitting layer, and the third electron transport layer is located between the third light emitting layer and the second electrode; electron mobility of the first electron transport layer is greater than electron mobility of the third electron transport layer.

For example, in the light emitting diode provided by an embodiment of the present disclosure, a material of the first electron transport layer is different from a material of the third electron transport layer.

For example, in the light emitting diode provided by an embodiment of the present disclosure, hole mobility of the second hole transport layer is smaller than that of the first hole transport layer.

For example, in the light emitting diode provided by an embodiment of the present disclosure, a difference between the absolute value of the first energy level difference and the absolute value of the second energy level difference ranges from 0.2 eV to 0.4 eV.

For example, in the light emitting diode provided by an embodiment of the present disclosure, the LUMO energy level of the first electron transport layer and the LUMO energy level of the first light emitting layer are substantially the same.

For example, in the light emitting diode provided by an embodiment of the present disclosure, the first charge generation layer comprises a first N-type charge generation sub-layer and a first P-type charge generation sub-layer, the first N-type charge generation sub-layer is located on a side of the first P-type charge generation sub-layer close to the first electron transport layer.

For example, in the light emitting diode provided by an embodiment of the present disclosure, the second charge generation layer comprises a second N-type charge generation sub-layer and a second P-type charge generation sub-layer, the second N-type charge generation sub-layer is located on a side of the second P-type charge generation sub-layer close to the second electron transport layer.

For example, in the light emitting diode provided by an embodiment of the present disclosure, the second light emitting structure further comprises a fourth light emitting layer located between the second light emitting layer and the second electron transport layer, and the second light emitting layer and the fourth light emitting layer are configured to emit light of different colors.

For example, in the light emitting diode provided by an embodiment of the present disclosure, the second light emitting layer is configured to emit light with a wavelength range of 610 nm to 640 nm, and the fourth light emitting layer is configured to emit light with a wavelength range of 520 nm to 540 nm.

For example, in the light emitting diode provided by an embodiment of the present disclosure, the second light emitting layer is configured to emit light with a wavelength range of 610 nm to 640 nm, and the fourth light emitting layer is configured to emit light with a wavelength range of 540 nm to 560 nm.

For example, in the light emitting diode provided by an embodiment of the present disclosure, the first light emitting layer and the third light emitting layer are configured to emit light of a same color.

For example, in the light emitting diode provided by an embodiment of the present disclosure, the first light emitting layer and the second light emitting layer are configured to emit light with a wavelength range of 450 nm to 470 nm.

For example, in the light emitting diode provided by an embodiment of the present disclosure, the first light emitting layer comprises a deuterium substituted material.

For example, in the light emitting diode provided by an embodiment of the present disclosure, the second light emitting layer comprises a P-type organic light emitting material.

For example, in the light emitting diode provided by an embodiment of the present disclosure, the first electrode is an anode, and the second electrode is a cathode.

At least one embodiment of the present disclosure further provides a display substrate, which includes: a driving substrate; and a plurality of light emitting diodes, located on the driving substrate, the plurality of light emitting diodes include any one of the above light emitting diodes.

At least one embodiment of the present disclosure further provides a display device, comprising the above display substrate.

### BRIEF DESCRIPTION OF DRAWINGS

In order to clearly illustrate the technical solution of the embodiments of the present disclosure, the drawings of the embodiments will be briefly described below; it is obvious that the described drawings are only related to some embodiments of the present disclosure and thus are not limitative of the present disclosure.

FIG. 1 is a schematic diagram of a structure of an organic light emitting diode provided by the present disclosure;

FIG. 2 is a schematic diagram of a structure of a light emitting diode provided by an embodiment of the present disclosure;

FIG. 3 is a schematic diagram of another structure of a light emitting diode provided by an embodiment of the present disclosure;

FIG. 4 is a schematic diagram of a structure of a display substrate provided by an embodiment of the present disclosure;

FIG. 5 is a schematic diagram of a structure of another display substrate provided by an embodiment of the present disclosure;

FIG. 6 is a schematic diagram of a structure of a display device provided by an embodiment of the present disclosure.

### DETAILED DESCRIPTION

In order to make objectives, technical details, and advantages of the embodiments of the present disclosure more clear, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Unless otherwise defined, the features such as “parallel”, “vertical”, and “identical” used in the embodiment of the present disclosure all include strictly defined situations such as “parallel”, “vertical”, and “identical”, as well as situations where “substantially parallel”, “substantially vertical”, and “substantially identical” contain certain errors. For example, the above “substantially” can indicate that the difference between the compared objects is 10% of the average value of the compared objects, or within 5%. In a case that the number of a component or an element is not specifically specified in the following embodiments of the present disclosure, it means that the component or the element can be one or multiple, or can be understood as at least one. “At least one” refers to one or more, and “a plurality of” refers to at least two.

Compared to the liquid crystal display technology, organic light emitting diode display devices (OLEDs) have significant advantages in the display field due to their fast response speed, wide color gamut, high contrast, lightweight design, self-illumination, and wide viewing angle. However, when driving the organic light emitting diode components for a long time, the driving voltage of the organic light emitting diode components will gradually increase due to the deterioration of the light emitting material, which is not conducive to the service life of the organic light emitting diode.

The series type light emitting diode connects two organic light emitting structures in series through a charge generation layer, which can greatly improve the service life and also has the advantages of low power consumption and high brightness. Therefore, the series type light emitting diodes have become a research hotspot.

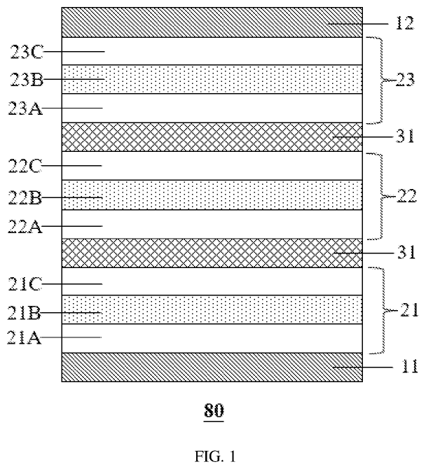

FIG. 1 is a schematic diagram of a structure of an organic light emitting diode provided by the present disclosure. As illustrated by FIG. 1, the organic light emitting diode 80 includes an anode 11, a first blue light emitting structure 21, a first charge generation layer 31, a red green light emitting structure 22, a second charge generation layer 32, a second blue light emitting structure 23 and a cathode 12. The first blue light emitting structure 21 includes a first hole transport layer 21A, a first blue light emitting layer 21B, and a first electron transport layer. The red green light emitting structure 22 includes a second hole transport layer 22A, a second red green light emitting layer 22B, and a second electron transport layer 22C. The second blue light emitting structure 23 includes a third hole transport layer 23A, a second blue light emitting layer 23B, and a third electron transport layer 23C. The blue light emitting structure 21 is located between the anode 11 and the first charge generation layer 31, the red green light emitting structure 22 is located between the first charge generation layer 31 and the second charge generation layer 32, and the second blue light emitting structure 23 is located between the second charge generation layer 32 and the cathode 12. The organic light emitting diode can achieve a white organic light emitting diode (WOLED) through the first blue light emitting structure 21, the red light emitting structure 22, and the second blue light emitting structure 23. Due to the series connection of a plurality of light emitting structures, the organic light emitting diode can greatly improve its service life, and also has the advantages of low power consumption and high brightness, in addition, due to the short lifespan of the blue light emitting material, the organic light emitting diode can further reduce the deterioration of the blue light emitting structure by setting two blue light emitting structures, thereby further improving its service life.

In the study, the inventor(s) of the present application noticed that in the above-mentioned organic light emitting diodes, the first blue light emitting structure and the second blue light emitting structure should theoretically achieve the same light emitting efficiency. However, in the experiment, the light emitting efficiency of the first blue light emitting structure is lower than that of the second blue light emitting structure. One reason for this phenomenon is that the cathode is made of metal materials, which can be regarded as an electron sea. There is an endless and unrestricted supply of electrons for injection into the second blue light emitting structure, while the amount or efficiency of electrons generated by the first charge generation layer injected into the first blue light emitting structure is limited by the potential barrier of the first charge generation layer injecting holes into the red green light emitting structure (mainly the red light emitting layer in the red green light emitting structure).

In this regard, embodiments of the present disclosure provide a light emitting diode, a display substrate and a display device. The light emitting diode comprises: a first electrode, a first light emitting structure, a first charge generation layer, a second light emitting structure and a second electrode; the first light emitting structure is located on a side of the first electrode, the first charge generation layer is located on a side of the first light emitting structure away from the first electrode, the second light emitting structure is located on a side of the first charge generation layer away from the first light emitting structure; and the second electrode is located on a side of the second light emitting structure away from the first charge generation layer. The first light emitting structure comprises a first hole transport layer, a first light emitting layer and a first electron transport layer, the first hole transport layer is located between the first electrode and the first light emitting layer, the first electron transport layer is located between the first charge generation layer and the first light emitting layer; the second light emitting structure comprises a second hole transport layer and a second light emitting layer, and the second hole transport layer is located between the first charge generation layer and the second light emitting layer, an absolute value of a first energy level difference between a LUMO energy level of the first light emitting layer and a LUMO energy level of the first electron transport layer is less than an absolute value of a second energy level difference between a HOMO energy level of the second light emitting layer and a HOMO energy level of the second hole transport layer. Therefore, the light emitting diode can increase the amount and efficiency of electrons generated by the first charge generation layer injected into the first blue light emitting structure, thereby improving the light emitting efficiency of the first blue light emitting structure.

Hereinafter, the light emitting diode, the display substrate, and the display device provided by the embodiments of the present disclosure will be described in detail with reference to the accompanying drawings.

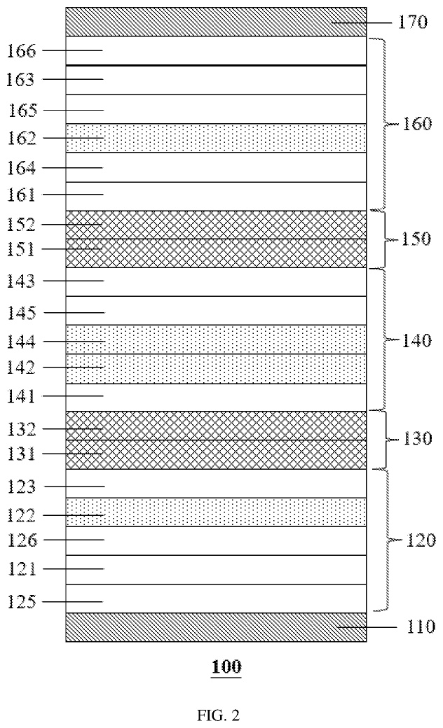

An embodiment of the present disclosure provides a light emitting diode. FIG. 2 is a schematic diagram of a structure of a light emitting diode provided by an embodiment of the present disclosure. The light emitting diode 100 includes a first electrode 110, a first light emitting structure 120, a first charge generation layer 130, a second light emitting structure 140, a second charge generation structure 150, a third light emitting structure 160, and a second electrode 170. The first light emitting structure 120 is located on a side of the first electrode 110, the first charge generation layer 130 is located on a side of the first light emitting structure 120 away from the first electrode 110, the second light emitting structure 140 is located on a side of the first charge generation layer 130 away from the first light emitting structure 120, and the second electrode 170 is located on a side of the second light emitting structure 140 away from the first charge generation layer 130. That is to say, the first light emitting structure 120 and the second light emitting structure 140 are connected in series through the first charge generation layer 130.

As illustrated by FIG. 2, the second charge generation layer 150 is located on a side of the second light emitting structure 140 away from the first charge generation layer 130. The third light emitting structure 160 is located between the second charge generation layer 150 and the second electrode 170. The second light emitting structure 140 further includes a second electron transport layer 143, and the second electron transport layer 143 is located between the second light emitting layer 142 and the second charge generation layer 150. That is to say, the second light emitting structure 140 and the third light emitting structure 160 are connected in series through the second charge generation layer 150.

As illustrated by FIG. 2, the first light emitting structure 120 includes a first hole transport layer 121, a first light emitting layer 122, and a first electron transport layer 123. The first hole transport layer 121 is located between the first electrode 110 and the first light emitting layer 122, and the first electron transport layer 123 is located between the first charge generation layer 130 and the first light emitting layer 122. The second light emitting structure 140 includes a second hole transport layer 141 and a second light emitting layer 142. The second hole transport layer 141 is located between the first charge generation layer 130 and the second light emitting layer 142. The absolute value of the first energy level difference between the LUMO level of the first light emitting layer 122 and the LUMO level of the first electron transport layer 123 is less than the absolute value of the second energy level difference between the HOMO level of the second light emitting layer 142 and the HOMO level of the second hole transport layer 141. That is to say, the absolute value of (LUMO energy level of the first light emitting layer-LUMO energy level of the first electron transport layer)>the absolute value of (HOMO energy level of the second light emitting layer-HOMO energy level of the second hole transport layer).

In some examples, the first light emitting layer and the third light emitting layer are configured to emit light of a same color. For example, the first light emitting layer and the second light emitting layer are configured to emit light with a wavelength range of 450 nm to 470 nm, that is blue light.

In the light emitting diode provided in the embodiment, on the one hand, the light emitting diode connects the first light emitting structure, the second light emitting structure, and the third light emitting structure in series through the first charge generation layer and the second charge generation layer, thereby greatly improving lifespan, reducing power consumption, and improving brightness. On the other hand, the absolute value of the first energy level difference between the LUMO level of the first light emitting layer and the LUMO level of the first electron transport layer is less than the absolute value of the second energy level difference between the HOMO level of the second light emitting layer and the HOMO level of the second hole transport layer. The potential barrier of electrons from the first charge generation layer to the first light emitting structure is small, and the potential barrier of holes from the first charge generation layer to the second light emitting structure is relatively large, thus, the electrons in the second light emitting structure are closer to the side where the first electrode is located, which can accelerate the electron transfer in the first light emitting structure and thereby improve the light emitting efficiency of the first light emitting structure. Moreover, due to the improvement of the light emitting efficiency of the first light emitting structure, the light emitting efficiency of the first light emitting structure and the light emitting efficiency of the third light emitting structure tend to be consistent, thereby balancing the service life of the first light emitting structure and the service life of the third light emitting structure, and the overall service life of the light emitting diode is extended. It should be noted that in the light emitting diodes, the HOMO level and the LUMO level mentioned above are both below the vacuum level (0 eV) and have negative values. The LUMO level of the first light emitting layer is generally smaller than the LUMO level of the first electron transport layer, while the HOMO level of the second light emitting layer is deeper than the HOMO level of the second hole transport layer.

On the other hand, the light emitting diode can reduce the amount of holes injected into the second light emitting structure by the first charge generation layer, which makes that the holes and the electrons in the second light emitting structure are more balanced, so that the light emitting efficiency of the second light emitting structure is improved.

In some examples, the difference between the absolute value of the first energy level difference and the absolute value of the second energy level difference ranges from 0.2 eV to 0.4 eV, for example, 0.3 eV. Therefore, the light emitting diode can better balance the service life of the first light emitting structure and the service life of the third light emitting structure.

In some examples, as illustrated by FIG. 2, the third light emitting structure 160 includes a third hole transport layer 161, a third light emitting layer 162, and a third electron transport layer 163. The third hole transport layer 161 is located between the second charge generation layer 150 and the third light emitting layer 162, and the third electron transport layer 163 is located between the third light emitting layer 162 and the second electrode 170. The electron mobility of the first electron transport layer 123 is greater than that of the third electron transport layer 163.

In the light emitting diode provided in the example, since the electron mobility of the first electron transport layer is greater than that of the third electron transport layer, the light emitting diode can improve the efficiency of transporting electrons from the first charge generation layer to the first light emitting structure, thereby further improving the light emitting efficiency of the first light emitting structure.

In some examples, the material of the first electron transport layer 123 is different from the material of the third electron transport layer 163, which results in a higher electron mobility of the first electron transport layer 123 than that of the third electron transport layer 163.

Table 1 shows the experimental data comparison between the first blue light emitting structure in the light emitting diode shown in FIG. 1 and the first light emitting structure in the light emitting diode shown in FIG. 2. As illustrated by Table 1, under the same current density, the current efficiency, the external quantum efficiency, and the blue efficiency index of the first emitting structure in the light emitting diode shown in FIG. 2 are all higher than those of the first blue light emitting structure in the light emitting diode shown in FIG. 1, respectively. It can be seen that by setting the absolute value of the first energy level difference between the LUMO level of the first light emitting layer and the LUMO level of the first electron transport layer to be less than the absolute value of the second energy level difference between the HOMO level of the second light emitting layer and the HOMO level of the second hole transport layer, and making the electron mobility of the first electron transport layer greater than that of the third electron transport layer, the light emitting diode shown in FIG. 2 can effectively improve the light emitting efficiency of the first light emitting structure. On the other hand, as illustrated by Table 1, under the same current density, the driving voltage of the first light emitting structure in the light emitting diode shown in FIG. 2 is lower than that of the first blue light emitting structure in the light emitting diode shown in FIG. 1, which can to some extent slow down the material degradation of the first light emitting layer and improve the service life of the first light emitting structure.

TABLE 1
Comparison of experimental data

| | | | | External | | | Blue light |
|---|---|---|---|---|---|---|---|
| | Current | Driving | Current | quantum | Chromatic | Chromatic | efficiency |
| | density | voltage | efficiency | efficiency | coordinates | coordinates | index |
| Device | (mA/cm²) | (V) | (cd/A) | (%) | CIEx | CIEy | (BI) |
| Product 1 | 10 | 11.54 | 13.9 | 13.3 | 0.141 | 0.120 | 115.6 |
| Product 2 | 10 | 11.40 | 14.4 | 13.8 | 0.140 | 0.120 | 120.2 |

In some examples, the LUMO energy level of the first electron transport layer is substantially the same as the LUMO energy level of the first light emitting layer, thereby reducing the absolute value of the first energy level difference.

In some examples, the LUMO energy level of the first electron transport layer is-3.0 eV, and the LUMO energy level of the first light emitting layer is-3.0 eV. The HOMO energy level of the second hole transport layer 141 is-5.5 eV, and the HOMO energy level of the second light emitting layer 142 is-5.8 eV.

In some examples, as illustrated by FIG. 2, the hole mobility of the second hole transport layer 141 is lower than that of the first hole transport layer 121. Therefore, the light emitting diode can reduce the hole mobility of the second hole transport layer, thereby balancing the carrier concentration in the second light emitting layer.

In some examples, as illustrated by FIG. 2, the hole mobility of the second hole transport layer 141 is lower than that of the third hole transport layer 161. Therefore, the light emitting diode can reduce the hole mobility of the second hole transport layer, thereby balancing the carrier concentration in the second light emitting layer.

In some examples, as illustrated by FIG. 2, the second light emitting structure 140 also includes a fourth light emitting layer 144, located between the second light emitting layer 142 and the second electron transport layer 143. The second light emitting layer 142 and the fourth light emitting layer 144 are configured to emit light of different colors.

In some examples, the second light emitting layer is configured to emit light with a wavelength range of 610 nm-640 nm, i.e. red light, and the fourth light emitting layer is configured to emit light with a wavelength range of 520 nm-540 nm, i.e. green light. Of course, the embodiments of the present disclosure include, but are not limited to, the second light emitting layer configured to emit light with a wavelength range of 610 nm-640 nm, i.e. red light, and the fourth light emitting layer configured to emit light with a wavelength range of 540 nm-560 nm, i.e. yellow light.

In some examples, the first light emitting layer 122 includes deuterium substituted materials, thereby improving the service life of the first light emitting layer. Of course, the third light emitting layer that emits the same color of light as the first light emitting layer can also include deuterium substituted materials.

In some examples, as illustrated by FIG. 2, when the second light emitting structure 140 includes a second light emitting layer 142 and a fourth light emitting layer 144, the second light emitting layer 142 is a P-type organic light emitting material, which can better transfer holes to the fourth light emitting layer 144, thereby improving the overall light emitting efficiency of the second light emitting structure.

In some examples, as illustrated by FIG. 2, the first electrode 110 is an anode and the second electrode 170 is a cathode.

In some examples, as illustrated by FIG. 2, the first electrode 110 is a reflecting electrode that can reflect light, and the second electrode 170 is a transmitting electrode or a semi-transparent and semi reflective electrode that can allow light transmission.

Of course, the embodiments of the present disclosure include, but are not limited to, the second electrode 170 can also be a reflecting electrode that reflects light, and the first electrode 110 can be a transmitting electrode or a semi-transparent and semi reflective electrode that can allow light transmission.

In some examples, as illustrated by FIG. 2, the first charge generation layer 130 includes a first N-type charge generation sub-layer 131 and a first P-type charge generation sub-layer 132. The first N-type charge generation sub-layer 131 is located on a side of the first P-type charge generation sub-layer 132 close to the first electron transport layer 123.

In some examples, as illustrated by FIG. 2, the second charge generation layer 150 includes a second N-type charge generation sub-layer 151 and a second P-type charge generation sub-layer 152. The second N-type charge generation sub-layer 151 is located on a side of the second P-type charge generation sub-layer 152 close to the second electron transport layer 163.

In some examples, as illustrated by FIG. 2, the first light emitting structure 120 further includes a hole injection layer 125 and an electron barrier layer 126. The hole injection layer 125 is located between the first electrode 110 and the first hole transport layer 121. The electron barrier layer 126 is located between the first hole transport layer 121 and the first light emitting layer 122, thereby balancing the carrier concentration in the first light emitting layer and improving the light emitting efficiency of the first light emitting structure.

In some examples, as illustrated by FIG. 2, the second light emitting structure 140 also includes a hole barrier layer 145 located between the second electron transport layer 143 and the fourth light emitting layer 144, thereby balancing the carrier concentration in the fourth light emitting layer and the second light emitting layer, and improving the overall light emitting efficiency of the second light emitting structure.

In some examples, as illustrated by FIG. 2, the third light emitting structure 160 further includes an electron barrier layer 164, a hole barrier layer 165, and an electron injection layer 166. The electron barrier layer 164 is located between the third hole transport layer 161 and the third light emitting layer 162, and the hole barrier layer 165 is located between the third light emitting layer 162 and the third electron transport layer 163, thereby balancing the carrier concentration between the third light emitting layer 162. The electron injection layer 166 is located between the second electrode 170 and the third electron transport layer 163, thereby improving the injection efficiency of the electrons.

An embodiment of the present disclosure also provides a light emitting diode. FIG. 3 is a schematic diagram of a structure of a light emitting diode provided in an embodiment of the present disclosure. As illustrated by FIG. 3, the light emitting diode 100 includes a first electrode 110, a first light emitting structure 120, a first charge generation layer 130, a second light emitting structure 140, and a second electrode 170. The first light emitting structure 120 is located on a side of the first electrode 110, the first charge generation layer 130 is located on a side of the first light emitting structure 120 away from the first electrode 110, the second light emitting structure 140 is located on a side of the first charge generation layer 130 away from the first light emitting structure 120, and the second electrode 170 is located on a side of the second light emitting structure 140 away from the first charge generation layer 130. That is to say, the first light emitting structure 120 and the second light emitting structure 140 are connected in series through the first charge generation layer 130.

As illustrated by FIG. 2, the first light emitting structure 120 includes a first hole transport layer 121, a first light emitting layer 122, and a first electron transport layer 123. The first hole transport layer 121 is located between the first electrode 110 and the first light emitting layer 122, and the first electron transport layer 123 is located between the first charge generation layer 130 and the first light emitting layer 122; The second light emitting structure 140 includes a second hole transport layer 141 and a second light emitting layer 142. The second hole transport layer 141 is located between the first charge generation layer 130 and the second light emitting layer 142. The absolute value of the first energy level difference between the LUMO level of the first light emitting layer 122 and the LUMO level of the first electron transport layer 123 is less than the absolute value of the second energy level difference between the HOMO level of the second light emitting layer 142 and the HOMO level of the second hole transport layer 141. That is to say, the absolute value of (LUMO level of the first light emitting layer-LUMO level of the first electron transport layer)>the absolute value of (HOMO level of the second light emitting layer-HOMO level of the second hole transport layer).

In the light emitting diode provided in the embodiment, on the one hand, the light emitting diode connects the first and second light emitting structures in series through the first charge generation layer and the second charge generating layer, thereby improving lifespan, reducing power consumption, and improving brightness. On the other hand, the absolute value of the first energy level difference between the LUMO level of the first light emitting layer and the LUMO level of the first electron transport layer is less than the absolute value of the second energy level difference between the HOMO level of the second light emitting layer and the HOMO level of the second hole transport layer. The potential barrier of electrons from the first charge generation layer to the first light emitting structure is small, and the potential barrier of holes from the first charge generation layer to the second light emitting structure is relatively large. The light-emitting diode can reduce the amount of holes injected into the second light emitting structure by the first charge generation layer, which makes that the holes and the electrons in the second light emitting structure more balanced, thereby also improving the light emitting efficiency of the second light emitting structure.

In some examples, as illustrated by FIG. 2, the first charge generation layer 130 includes a first N-type charge generation sub-layer 131 and a first P-type charge generation sub-layer 132. The first N-type charge generation sub-layer 131 is located on a side of the first P-type charge generation sub-layer 132 close to the first electron transport layer 123.

In some examples, as illustrated by FIG. 2, the first light emitting structure 120 further includes a hole injection layer 125 and an electron barrier layer 126. The hole injection layer 125 is located between the first electrode 110 and the first hole transport layer 121. The electron barrier layer 126 is located between the first hole transport layer 121 and the first light emitting layer 122, thereby balancing the carrier concentration in the first light emitting layer and improving the light emitting efficiency of the first light emitting structure.

In some examples, as illustrated by FIG. 2, the second light emitting structure 140 also includes a hole barrier layer 145 located between the second electron transport layer 143 and the fourth light emitting layer 144, thereby balancing the carrier concentration in the fourth light emitting layer and the second light emitting layer, and improving the overall light emitting efficiency of the second light emitting structure.

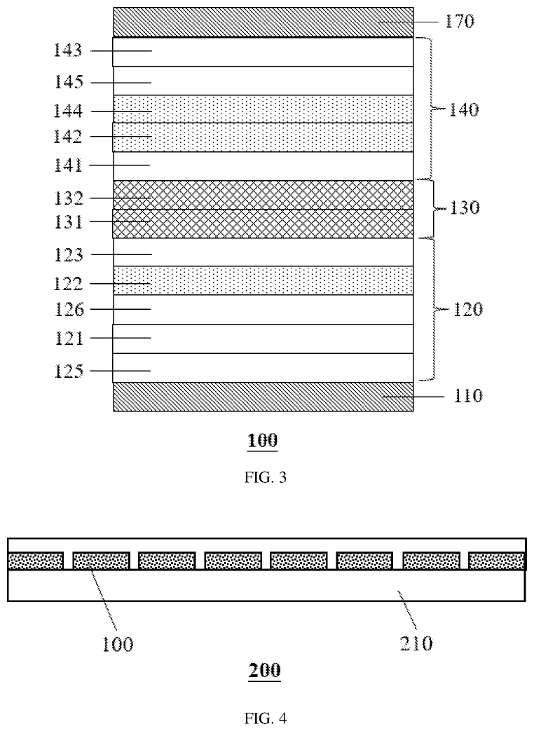

An embodiment of the present disclosure also provides a display substrate. FIG. 4 is a schematic diagram of a structure of a display substrate provided by an embodiment of the present disclosure. As illustrated by FIG. 4, the display substrate 200 includes a driving substrate 210 and a plurality of light emitting diodes 100, located on the driving substrate 210. The above plurality of light emitting diodes 100 include the light emitting diodes 100 provided in any one of the above examples. Therefore, due to the advantages of long service life, high light emitting efficiency, low power consumption, and high brightness of the LED, the display substrate using the LED also has advantages such as long service life, high light emitting efficiency, low power consumption, and high brightness.

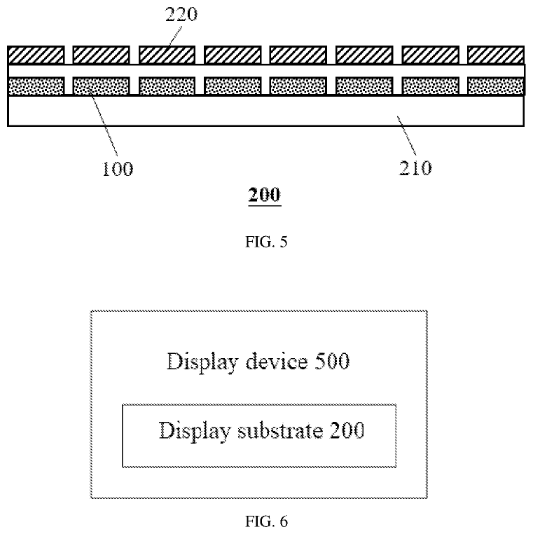

FIG. 5 is a schematic diagram of a structure of another display substrate provided by an embodiment of the present disclosure. As illustrated by FIG. 5, the display substrate 200 also includes a color film layer 220 located on the side of the plurality of light emitting diodes 100 away from the driving substrate 210. Therefore, in a case that the LED is a white LED, the display substrate can achieve color display by setting a color film layer.

An embodiment of the present disclosure further provides a display device. FIG. 6 is a schematic diagram of a display device provided by an embodiment of the present disclosure. As illustrated by FIG. 6, the display device 500 includes the aforementioned display substrate 200. Therefore, the display device has a technical effect corresponding to the beneficial technical effect of the liquid crystal display panel it includes.

For example, the display device can be an electronic product with display functions such as a television, a monitor, an electronic picture frame, an electronic photo frame, a navigator, a laptop computer, a tablet computer, a smartphone, etc.

The following statements should be noted:
(1) In the accompanying drawings of the embodiments of the present disclosure, the drawings involve only the structure(s) in connection with the embodiment(s) of the present disclosure, and other structure(s) can be referred to common design(s).
(2) In the case of no conflict, features in one embodiment or in different embodiments can be combined.

What have been described above are only specific implementations of the present disclosure, the protection scope of the present disclosure is not limited thereto, and the protection scope of the present disclosure should be based on the protection scope of the claims.

1. A light emitting diode, comprising:
a first electrode;
a first light emitting structure, located on a side of the first electrode;
a first charge generation layer, located on a side of the first light emitting structure away from the first electrode;
a second light emitting structure, located on a side of the first charge generation layer away from the first light emitting structure; and
a second electrode, located on a side of the second light emitting structure away from the first charge generation layer;
wherein the first light emitting structure comprises a first hole transport layer, a first light emitting layer and a first electron transport layer, the first hole transport layer is located between the first electrode and the first light emitting layer, and the first electron transport layer is located between the first charge generation layer and the first light emitting layer;
the second light emitting structure comprises a second hole transport layer and a second light emitting layer, the second hole transport layer is located between the first charge generation layer and the second light emitting layer, an absolute value of a first energy level difference between a LUMO energy level of the first light emitting layer and a LUMO energy level of the first electron transport layer is less than an absolute value of a second energy level difference between a HOMO energy level of the second light emitting layer and a HOMO energy level of the second hole transport layer.

2. The light emitting diode according to claim 1, further comprising:
a second charge generation layer, located on a side of the second light emitting structure away from the first charge generation layer; and
a third light emitting structure, located between the second charge generation layer and the second electrode;
wherein the second light emitting structure further comprises a second electron transport layer, and the second electron transport layer is located between the second light emitting layer and the second charge generation layer.

3. The light emitting diode according to claim 2, wherein the third light emitting structure comprises a third hole transport layer, a third light emitting layer and a third electron transport layer, the third hole transport layer is located between the second charge generation layer and the third light emitting layer, and the third electron transport layer is located between the third light emitting layer and the second electrode;
electron mobility of the first electron transport layer is greater than electron mobility of the third electron transport layer.

4. The light emitting diode according to claim 3, wherein a material of the first electron transport layer is different from a material of the third electron transport layer.

5. The light emitting diode according to claim 1, wherein hole mobility of the second hole transport layer is smaller than that of the first hole transport layer.

6. The light emitting diode according to claim 1, wherein a difference between the absolute value of the first energy level difference and the absolute value of the second energy level difference ranges from 0.2 eV to 0.4 eV.

7. The light emitting diode according to claim 1, wherein the LUMO energy level of the first electron transport layer and the LUMO energy level of the first light emitting layer are substantially the same.

8. The light emitting diode according to claim 1, wherein the first charge generation layer comprises a first N-type charge generation sub-layer and a first P-type charge generation sub-layer, the first N-type charge generation sub-layer is located on a side of the first P-type charge generation sub-layer close to the first electron transport layer.

9. The light emitting diode according to claim 2, wherein the second charge generation layer comprises a second N-type charge generation sub-layer and a second P-type charge generation sub-layer, the second N-type charge generation sub-layer is located on a side of the second P-type charge generation sub-layer close to the second electron transport layer.

10. The light emitting diode according to claim 1, wherein the second light emitting structure further comprises a fourth light emitting layer located between the second light emitting layer and the second electron transport layer, and the second light emitting layer and the fourth light emitting layer are configured to emit light of different colors.

11. The light emitting diode according to claim 10, wherein the second light emitting layer is configured to emit light with a wavelength range of 610 nm to 640 nm, and the fourth light emitting layer is configured to emit light with a wavelength range of 520 nm to 540 nm.

12. The light emitting diode according to claim 10, wherein the second light emitting layer is configured to emit light with a wavelength range of 610 nm to 640 nm, and the fourth light emitting layer is configured to emit light with a wavelength range of 540 nm to 560 nm.

13. The light emitting diode according to claim 3, wherein the first light emitting layer and the third light emitting layer are configured to emit light of a same color.

14. The light emitting diode according to claim 13, wherein the first light emitting layer and the second light emitting layer are configured to emit light with a wavelength range of 450 nm to 470 nm.

15. The light emitting diode according to claim 1, wherein the first light emitting layer comprises a deuterium substituted material.

16. The light emitting diode according to claim 1, wherein the second light emitting layer comprises a P-type organic light emitting material.

17. The light emitting diode according to claim 1, wherein the first electrode is an anode, and the second electrode is a cathode.

18. A display substrate, comprising:
a driving substrate; and
a plurality of light emitting diodes, located on the driving substrate,
wherein the plurality of light emitting diodes comprise the light emitting diodes according to claim 1.

19. A display device, comprising the display substrate according to claim 18.
